(19) United States
(12) Patent Application Publication
(10) Pub. No.: US 2008/0090314 A1
(43) Pub. Date: Apr. 17, 2008

(54) SEMICONDUCTOR DEVICE AND MANUFACTURING METHOD OF THE SAME

(76) Inventors: Seiichi Ichihara, Tokyo (JP); Atsushi Obuchi, Nanae (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/859,243

(22) Filed: Sep. 21, 2007

(30) Foreign Application Priority Data
Oct. 12, 2006 (JP) 2006-278480

(51) Int. Cl. H01L 21/66; H01L 23/58

(52) U.S. Cl. 438/18; 257/48; 257/E21.531

(57) ABSTRACT

It is in offering the technology which can solve the problem actualized in connection with the narrowing of a pitch of a bump electrode. Concretely, even if it is a case where the contact position of the probe needle to a bump electrode shifts, in the needle contact of the probe needle in an electrical property test, the technology in which it can prevent that a probe needle contacts an adjoining bump electrode is offered. Bump electrodes are arranged in a single line, and they are arranged so that a partial area may shift in an adjoining bump electrode. And a probe needle is contacted to the region which has shifted and an electrical property test is carried out.

### CROSS-REFERENCE TO RELATED APPLICATION

The present application claims priority from Japanese patent application No. 2006-278480 filed on Oct. 12, 2006, the content of which is hereby incorporated by reference into this application.

### BACKGROUND OF THE INVENTION

1. Field of the Invention

The present invention relates to a semiconductor device and its manufacturing technology, and particularly relates to an effective technology in the application to the driver for LCD (Liquid Crystal Display) which drives a liquid crystal display device, and its manufacture.

2. Description of the Background Art

In Japanese patent laid-open No. 2004-134471 (Patent Reference 1), the technology which forms the pad of one regular size in a semiconductor chip altogether, and forms a bump electrode which is different, respectively changing the size and arrangement of a bump electrode according to a mounting form on this pad is described. According to this technology, it is supposed that it is easy to do custom-made correspondence in the mounting form of a semiconductor chip, and development TAT can be shortened.

[Patent Reference 1] Japanese patent laid-open No. 2004-134471

### SUMMARY OF THE INVENTION

In recent years, LCD (Liquid Crystal Display) which used the liquid crystal for the display device is spreading quickly. This LCD is controlled by the driver for driving LCD. The driver for LCD comprises a semiconductor chip, for example, is mounted in a glass substrate. The semiconductor chip which forms the driver for LCD is having structure in which a plurality of transistors and multilayer interconnection were formed on the semiconductor substrate, and the bump electrode is formed in the front surface. And the semiconductor chip is mounted in the glass substrate via the bump electrode formed in the front surface. Although a glass substrate is connected with a semiconductor chip by the bump electrode at this time, electric connection between a bump electrode and the wiring formed in the glass substrate is made by the electric conduction particles which form an anisotropic conductive film (ACF). From a viewpoint which improves the reliability of the electric connection by this electric conduction particle, in order to make electric conduction particles intervene so much between a semiconductor chip and a glass substrate, enlarging area of the bump electrode of a semiconductor chip is performed. That is, the bump electrode of the semiconductor chip which forms the driver for LCD has the feature that the size is large far compared with the bump electrode of the semiconductor chip used for the semiconductor device which does not intervene electric conduction particles between mounting substrates.

The bump electrode is formed in the semiconductor chip which forms the driver for LCD as mentioned above. A plurality of these bump electrodes are formed in the semiconductor chip, and are arranged in a single line along the side of the semiconductor chip which has rectangular shape. A semiconductor chip is formed by individually separating the chip area of a semiconductor wafer. Before individually separating to a semiconductor chip, a plurality of bump electrodes will be formed in the chip area of a semiconductor wafer. In the semiconductor wafer in which a plurality of bump electrodes were formed to the chip area, before individually separating a chip area and making it a semiconductor chip, an electrical property test of the semiconductor element formed in the chip area is carried out in the state of a semiconductor wafer. An electrical property test of a semiconductor element is conducted by contacting a probe needle to the bump electrode formed in the chip area.

FIG. 29 is a plan view showing the adjacent bump electrode formed in the chip area of a semiconductor wafer. As shown in FIG. 29, passivation film 101 is formed on the surface of the chip area, and bump electrodes 102a and 102b are formed in this passivation film 101. Bump electrodes 102a and 102b show the bump electrode which adjoins each other mutually, and although not illustrated, a plurality of bump electrodes are arranged along one side of a chip area. Bump electrodes 102a and 102b has the plane form of rectangular form, and are arranged in the short side direction. Concretely, the size of the short side direction of bump electrodes 102a and 102b is about 16 μm, for example, and the size between adjacent bump electrode 102a and adjacent bump electrode 102b is about 14 μm, for example. Therefore, the pitch between bump electrodes 102a and 102b constitutes about 30 μm.

FIG. 30 is a cross-sectional view showing the section cut by the A-A line of FIG. 29. Semiconductor elements (not shown), such as a transistor, are formed in a semiconductor wafer, and the multi-layer structure of an interlayer insulation film and a wiring is formed on the semiconductor element. In FIG. 30, insulating film 103 which is an interlayer insulation film of the top layer is illustrated. On insulating film 103, for example, bonding pads 104a and 104b which consist of an aluminum film are formed, and passivation film 101 is formed so that bonding pads 104a and 104b may be covered. The opening is formed in passivation film 101 on bonding pads 104a and 104b, and bump electrodes 102a and 102b are formed on this opening. These bump electrodes 102a and 102b are electrically connected with bonding pads 104a and 104b, respectively.

A state that an electrical property test is conducted contacting a probe needle to bump electrodes 102a and 102b formed in this way is shown in the FIG. 31 which is a plan view. As shown in FIG. 31, probe needles 105a and 105b touch bump electrodes 102a and 102b, respectively. A state that the point of probe needles 105a and 105b contacts bump electrodes 102a and 102b is shown by FIG. 31. The point of probe needles 105a and 105b has circular form, and the diameter is about 10 μm˜20 μm, for example. The circle of the solid line shows a state that probe needles 105a and 105b contact bump electrodes 102a and 102b in an ideal position.

Here, as shown in FIG. 31, in adjoining bump electrodes 102a and 102b, the positions where probe needles 105a and 105b contact differ. That is, arrangement of adjacent probe needles 105a and 105b is set as staggered arragement. Hereby, even if between bump electrodes 102a and 102b becomes narrow, it can be prevented that adjoining probe needles 105a and 105b contact. Thus, corresponding to the narrowing of a pitch between bump electrodes 102a and 102b, arrangement of probe needles 105a and 105b is devised.

Probe needles 105a and 105b in contact with bump electrodes 102a and 102b contact ideally in the position of the circle of the solid line shown in FIG. 31. However, a drift may occur with the accuracy of position of probe needles 105a and 105b. This is because the electrical property test is conducted using the probe device of a cantilever method. In the case of a cantilever method, the form of probe needles 105a and 105b comprises a state in which elastic deformation is possible, bump electrodes 102a and 102b are made to contact pushing and pressing the tip of probe needles 105a and 105b, and an electrical connection is aimed at. However, the form at the tip of probe needle 105b in a cantilever method is formed in the shape of an L character, as shown in FIG. 32. The tip of probe needle 105b will move by the tip of probe needle 105b being pushed and pressed horizontally by an elastic action, and it will shift from the position which the tip of probe needle 105b originally wants to contact in it. The circle of the dashed line shows the case where the contact position of probe needles 105a and 105b has shifted. Since the grade of a position drift of probe needles 105a and 105b is ±3 μm grade, as described to FIG. 29, when the pitch between bump electrodes 102a and 102b is about 30 μm, even if the position of probe needles 105a and 105b shifts, the problem of contacting and short-circuiting to an adjoining bump electrode is avoidable. The cross-sectional view cut by the A-A line of FIG. 31 is shown in FIG. 32. Even if probe needle 105b causes a position drift as FIG. 32 may be seen and understood, it turns out that probe needle 105b does not contact adjoining bump electrode 102a.

However, in connection with a miniaturization and high definition of LCD, the number of bump electrodes for the output of the driver for LCD is increasing in recent years. For this reason, the distance between bump electrodes is becoming narrow. For example, as shown in FIG. 33, the length of the short side direction of bump electrodes 102a and 102b which has the rectangle is about 10 μm, and the distance between adjacent bump electrodes 102a and 102b is reduced to about 8 μm. Therefore, the pitch between adjacent bump electrodes 102a and 102b is about 18 μm.

A state that applies a probe needle to the semiconductor chip which has such a bump electrode, and an electrical property test is carried out is shown in FIG. 33. In FIG. 33, the circle of the solid line shows the case where probe needles 105a and 105b contact bump electrodes 102a and 102b in an ideal position. When carrying out an electrical property test, it is desirable to contact probe needles 105a and 105b to bump electrodes 102a and 102b in an ideal position, as the circle of a solid line shows.

However, as for probe needles 105a and 105b, a contact position may shift from the problem of accuracy of position. The circle of the dashed line shows a state that it shifts from an ideal position and probe needles 105a and 105b contact bump electrodes 102a and 102b at FIG. 33. As for the semiconductor chip shown in FIG. 31 and FIG. 32, when a position drift of probe needles 105a and 105b occurs, since the pitch between bump electrodes 102a and 102b was secured to some extent, it was avoidable that probe needles 105a and 105b contact adjoining bump electrodes 102a and 102b. However, as for the semiconductor chip shown in FIG. 33, since the pitch between bump electrodes 102a and 102b is narrow, when probe needles 105a and 105b cause a position drift, the problem that probe needles 105a and 105b contact adjoining bump electrodes 102a and 102b will occur. When probe needles 105a and 105b contact adjoining bump electrodes 102a and 102b, since adjoining bump electrodes 102a and 102b short-circuit via probe needles 105a and 105b, it will become impossible to conduct a normal electrical property test. The cross-sectional view cut by the A-A line of FIG. 33 is shown in FIG. 34. As shown in FIG. 34, when the position of probe needle 105b which contacts bump electrode 102b shifting (a dashed line showing) from an ideal position (a solid line showing), it turns out that probe needle 105b contacts adjoining bump electrode 102a. The above thing shows that a short circuit defect will happen easily by position drift of probe needles 105a and 105b when the pitch between bump electrodes 102a and 102b becomes narrow.

As a method of preventing the short circuit defect by position drift of probe needles 105a and 105b, it is possible to make small the tip diameter of probe needles 105a and 105b. By making small the tip diameter of probe needles 105a and 105b, even if a position drift occurs in probe needles 105a and 105b, it can be suppressed that probe needles 105a and 105b contact adjoining bump electrodes 102a and 102b, and the short circuit defect in an electrical property test can be reduced.

However, by the method mentioned above, a probe needle with a thin tip diameter will newly be used, without using a conventional probe needle. That is, it is necessary to newly manufacture a probe needle with a thin tip diameter instead of a conventional probe needle. Then, since a new probe needle will be manufactured, there is a problem that a manufacturing cost rises. The probe needle with a thin tip diameter also has the problem that a lifetime becomes short. Thus, although the short circuit defect by position drift of a probe needle can be reduced by making the tip diameter of a probe needle thin, it turns out that the problem that a manufacturing cost will rise occurs.

As an option, it is possible to use not the probe device of a cantilever method but the probe device of a thin film probe method in which the tip of a probe needle moves only perpendicularly. However, since the movement mechanism becomes more complicated than a cantilever method in the case of a thin film probe method, the cost of equipment will be high and the manufacturing cost of a semiconductor device will increase. Even if the thin film probe method is used, the problem of the position drift generated when the tip of a probe needle contacts a bump electrode is not suppressed thoroughly. When the pitch between adjacent bump electrodes becomes narrower in connection with a narrowing of a pitch, even if a thin film probe method will be used, short circuit defect in an electrical property test cannot be prevented.

As an option, as shown in FIG. 35, how to arrange a plurality of bump electrodes (bump electrode for an output) 107 by turns along the short side direction of semiconductor chip 106 alternately (staggered arragement) can be considered. When arranging bump electrode 107 alternately, since the next bump electrode 107 will not be arranged around the region where the tip of a probe needle contacts, even if a drift will occur in the contact position of a probe needle, it is possible to suppress short circuit defect. However, when arranging a plurality of bump electrodes 107 alternately, in the short side direction of semiconductor chip 106, by a part for the region in which bump electrode 107 is arranged at two rows, the size of semiconductor chip 106 will become large. Hereby, it is difficult to realize the miniaturization of a semiconductor device. The drawing of the wiring from each of a plurality of bump electrodes 107 arranged alternately becomes complicated compared with the case where bump electrode 107 has been arranged at one row, and the cost reduction of a semiconductor device becomes difficult. Even if it only arranges a plurality of bump electrodes 107 alternately, when the distance between adjacent bump electrodes 107 becomes narrower, the amount of drifts of the contact position at the tip of a probe needle surpasses rather than the distance which is between bump electrodes 107, and it is difficult too to suppress the problem of short circuit defect mentioned above.

A purpose of the present invention is to offer the technology which can solve the problem actualized in connection with the narrowing of a pitch of a bump electrode. Concretely, even if it is a case where the contact position of the probe needle to a bump electrode shifts, in the needle contact of the probe needle in an electrical property test, it is in offering the technology which can prevent that a probe needle contacts an adjoining bump electrode.

The above-described and the other purposes and novel features of the present invention will become apparent from the description herein and accompanying drawings.

Of the inventions disclosed in the present application, typical ones will next be summarized briefly.

A method of manufacturing a semiconductor device by the present invention comprises the steps of (a) forming a plurality of bump electrodes in a chip area of a semiconductor wafer, and (b) conducting an electrical property test by contacting a probe needle to which staggered arragement is done in the bump electrodes. And, a bump electrode which adjoins each other among the bump electrodes is formed each partial area shifting mutually.

And, a semiconductor device by the present invention comprises a semiconductor chip in which a plurality of bump electrodes are formed, wherein as for a bump electrode which adjoins each other among the bump electrodes, each partial area is shifted mutually.

Advantages achieved by some of the most typical aspects of the invention disclosed in the present application will be briefly described below.

Since the bump electrode which adjoins each other among a plurality of bump electrodes was formed so that each partial area might shift mutually, in the needle contact of the probe needle in an electrical property test, even if it is a case where the contact position of the probe needle to a bump electrode shifts, it can be prevented that a probe needle contacts an adjoining bump electrode.

### BRIEF DESCRIPTION OF THE DRAWINGS

FIG. 1 is a plan view showing the semiconductor chip in Embodiment 1 of the present invention;

FIG. 2 is a drawing expanding and showing the bump electrode for an output shown in FIG. 1;

FIG. 3 is a drawing showing a state that an electrical property test is carried out contacting the bump electrode for an output in a probe needle;

FIG. 4 is a drawing showing a state that probe marks are formed in the bump electrode for an output;

FIG. 5 is a drawing explaining the definition of structure of that a bump electrode is arranged in a single line, and a partial area shifts and is arranged in the adjoining bump electrode;

FIG. 6 is a drawing showing the example which is not included in the arrangement from which the bump electrode was arranged in a single line, and the partial area has shifted in the adjoining bump electrode;

FIG. 7 is a drawing showing the structure of the glass substrate which mounts the semiconductor chip which has the bump electrode by which staggered arragement was done;

FIG. 8 is a drawing showing the structure of the glass substrate which mounts the semiconductor chip which has a bump electrode arranged in a single line;

FIG. 9 is a drawing showing the structure of the glass substrate which mounts the semiconductor chip in the present invention;

FIG. 10 is a cross-sectional view showing the manufacturing process of the semiconductor device in Embodiment 1;

FIG. 11 is a cross-sectional view showing the manufacturing process of a semiconductor device following FIG. 10;

FIG. 12 is a cross-sectional view showing the manufacturing process of a semiconductor device following FIG. 11;

FIG. 13 is a cross-sectional view showing the manufacturing process of a semiconductor device following FIG. 12;

FIG. 14 is a cross-sectional view showing the manufacturing process of a semiconductor device following FIG. 13;

FIG. 15 is a cross-sectional view showing the manufacturing process of a semiconductor device following FIG. 14;

FIG. 16 is a drawing showing the plane configuration of a bump electrode;

FIG. 17 is an outline view showing the probe device of a cantilever method;

FIG. 18 is a cross-sectional view showing the section cut by the A-A line of FIG. 17;

FIG. 19 is a drawing showing a state that a probe needle is contacted in a bump electrode;

FIG. 20 is a plan view showing the position in which a probe needle is contacted in a bump electrode;

FIG. 21 is a plan view showing a state that probe marks are formed in a bump electrode;

FIGS. 22 and 23 are cross-sectional views showing a state that a semiconductor chip is mounted in a glass substrate;

FIG. 24 is a cross-sectional view showing the example which mounts a semiconductor chip in a liquid crystal display device;

FIG. 25 is a drawing showing the structure of a liquid crystal display device;

FIG. 26 is a plan view showing the semiconductor chip in Embodiment 2;

FIG. 27 is a drawing expanding and showing the bump electrode for an output shown in FIG. 26;

FIG. 28 is a drawing showing the structure of the glass substrate which mounts the semiconductor chip which has the bump electrode by which staggered arragement was done;

FIG. 29 is a drawing which present inventors examined, and is a plan view showing the adjacent bump electrode formed in the chip area of a semiconductor wafer;

FIG. 30 is a cross-sectional view cut by the A-A line of FIG. 29;

FIG. 31 is a drawing which present inventors examined, and is a plan view showing a state that an electrical property test is conducted contacting a probe needle in a bump electrode;

FIG. 32 is a cross-sectional view cut by the A-A line of FIG. 31;

FIG. 33 is a drawing which present inventors examined, and is a plan view showing a state that an electrical property test is conducted contacting a probe needle in the bump electrode which did the narrowing of a pitch;

FIG. 34 is a cross-sectional view cut by the A-A line of FIG. 33; and

FIG. 35 is a drawing which present inventors examined, and is a plan view showing the example which did staggered arragement of the bump electrode for an output.

### DETAILED DESCRIPTION OF THE PREFERRED EMBODIMENTS

In the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated.

And, in the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number.

Further, in the below-described embodiments, it is needless to say that the constituting elements (including element steps) are not always essential unless otherwise specifically indicated or principally apparent that they are essential.

Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range.

And, in all the drawings for describing the embodiments, members of a like function will be identified by like reference numerals in principle and overlapping descriptions will be omitted. Hatching may be attached even if it is a plan view, in order to make a drawing intelligible.

### Embodiment 1

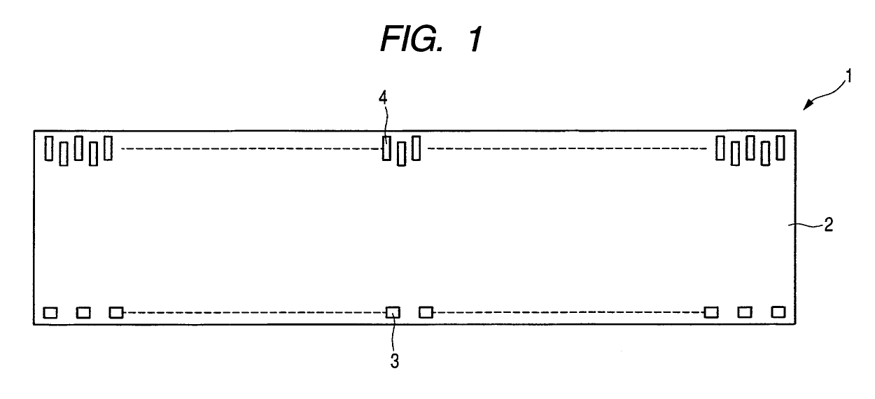

FIG. 1 is a plan view showing the layout structure of semiconductor chip 1 (semiconductor device) in Embodiment 1. Semiconductor chip 1 in Embodiment 1 is used as a driver for LCD. In FIG. 1, semiconductor chip 1 has semiconductor substrate 2 whose plane form is long and slender rectangular form, for example, and the driver for LCD which drives a liquid crystal display device is formed in the main surface, for example. This driver for LCD has a function which supplies voltage to each pixel of the cell array which forms LCD, and controls the direction of a liquid crystal molecule.

Among the drivers for LCD which drive a liquid crystal display device, the driver for LCD which drives the liquid crystal display device of an STN (Super Twisted Nematic) method is mentioned as an example, and Embodiment 1 explains it. An STN method is one of the drive systems of a liquid crystal display device, and is a simple matrix method. That is, it is a method that the direction of the liquid crystal molecule in an intersection region (cell) changes, and a liquid crystal display device drives when lead wire is spread around in the two directions of an X axial direction and a Y axial direction which cross mutually and voltage is applied to lead wire from the two directions of an X axial direction and a Y axial direction. It is mentioned as an advantage of an STN method that it can be manufactured by low cost.

FIG. 1 is a drawing showing the driver for LCD used for the liquid crystal display device of an STN method. As shown in FIG. 1, near the periphery of semiconductor chip 1, a plurality of bump electrodes are arranged for every prescribed interval along the periphery of semiconductor chip 1. Bump electrode 3 is formed in one long side of rectangular semiconductor chip 1. Bump electrode 3 is an electrode for inputting an input signal into the inside of semiconductor chip 1. On the other hand, bump electrode 4 is formed in another long side of semiconductor chip 1. This bump electrode 4 is an electrode for outputting an output signal to a liquid crystal display from semiconductor chip 1 which is a driver for LCD. That is, bump electrode 4 is formed corresponding to each of X shaft electrode and Y shaft electrode which are spread around by the liquid crystal display. Although FIG. 1 shows the example in which bump electrode 4 is not formed at the short side of semiconductor chip 1, bump electrode 4 for an output may be formed along both short sides of semiconductor chip 1 with advanced features and a miniaturization of a semiconductor device. Although bump electrode 3 for an input is formed along one long side of semiconductor chip 1 and bump electrode 4 for an output is formed along another long side of semiconductor chip 1 in FIG. 1, bump electrode 4 for an output may be formed in a part of long side in which bump electrode 3 for an input is formed.

In the driver for LCD formed in this way, there is the feature that the number of bump electrodes 4 for an output increases, compared with the number of bump electrodes 3 for an input. Therefore, the gap of bump electrode 4 for an output is narrow rather than the gap of bump electrode 3 for an input. In the driver for LCD used for the liquid crystal display device of an STN method, as shown in FIG. 1, both bump electrode 3 for an input and bump electrode 4 for an output are arranged in a single line along the long side direction of semiconductor chip 1 in many cases. Usually, bump electrode 4 for an output as well as bump electrode 3 for an input is arranged in a single line exactly, without shifting.

Here, one of the features of the present invention is in the locating position of bump electrode 4 for an output. That is, as shown in FIG. 1, bump electrode 4 for an output is arranged in a single line along the long side of semiconductor chip 1, but the feature is at the point that each partial area is formed shifting along the short side direction of semiconductor chip 1 mutually in adjacent bump electrode 4.

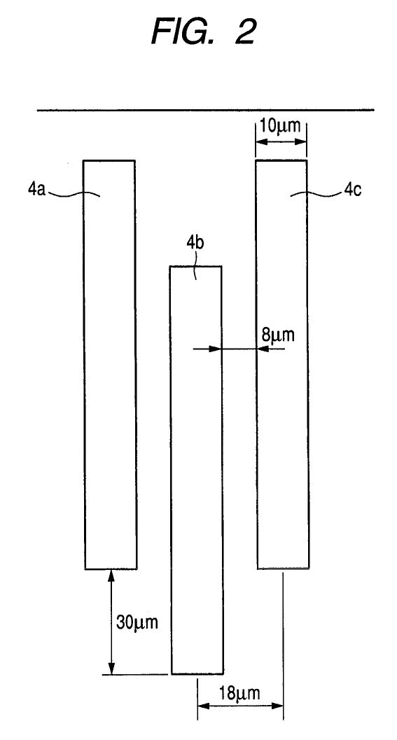

This characteristic point is explained. FIG. 2 is the drawing which expanded a part of region which forms bump electrode 4 for an output shown in FIG. 1. In FIG. 2, bump electrodes 4a-4c for an output are located in a line in a single line, and are arranged. At this time, adjoining bump electrode 4a and adjoining bump electrode 4b are arranged so that a partial area may shift mutually, and similarly, adjoining bump electrode 4b and adjoining bump electrode 4c are also arranged so that a partial area may shift mutually.

Concretely, bump electrodes 4a-4c for an output have rectangular form, and the length of a short side direction is about 10 μm. The gap between bump electrode 4a and bump electrode 4b constitutes 8 μm. Similarly, the gap between bump electrode 4b and bump electrode 4c also constitutes 8 μm. Therefore, the pitch of bump electrodes 4a-4c for an output constitutes about 18 μm. And bump electrode 4b is shifted to the long side direction of bump electrodes 4a-4c only about 30 μm to bump electrodes 4a and 4c at the lower part. Thus, in bump electrodes 4a-4c for an output arranged in a single line, adjoining bump electrode 4a and adjoining bump electrode 4b (it can be said also as adjoining bump electrode 4b and adjoining bump electrode 4c) are arranged so that a partial area may shift mutually. This point is one of the features of the present invention, and it explains, referring to a drawing for the advantage below.

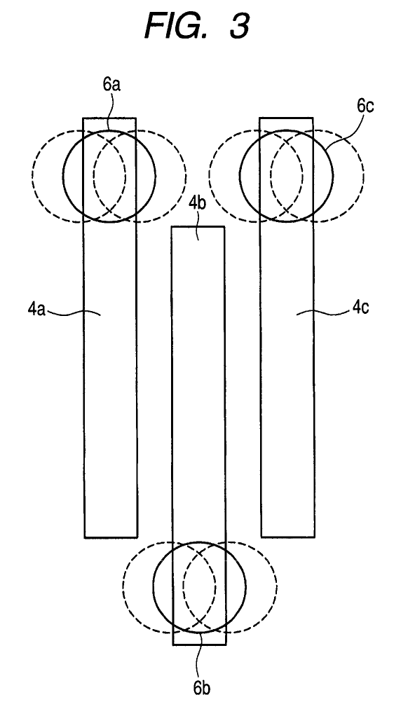

FIG. 3 is a drawing showing a state that an electrical property test is carried out contacting probe needles 6a-6c to bump electrodes 4a-4c. An electrical property test is carried out in the state of the semiconductor wafer before individually separating to a semiconductor chip. That is, FIG. 3 shows bump electrodes 4a-4c formed in the chip area of a semiconductor wafer, and is contacting probe needles 6a-6c on these bump electrodes 4a-4c.

First, probe needles 6a-6c are alternately arranged as a premise explaining the feature of the present invention. For example, in adjoining bump electrode 4a and adjoining bump electrode 4b, the positions where probe needles 6a and 6b contact differ. That is, as shown in FIG. 3, in bump electrode 4a, probe needle 6a touches the end side of bump electrode 4a. On the other hand, in bump electrode 4b, probe needle 6b touches the other end side of bump electrode 4b. Thus, probe needles 6a-6c are arranged alternately. Probe needles 6a and 6b are contacted in the position mutually separated with adjoining bump electrode 4a and adjoining bump electrode 4b. Adjoining probe needles 6a and 6b are kept from contacting mutually by this.

In recent years, in connection with the high definition of LCD, the number of the bump electrodes formed in the driver for LCD is increasing. For example, in the driver for LCD used for the liquid crystal display device of an STN method, as shown in FIG. 1, bump electrode 4 for an output is arranged in a single line in the long side direction of semiconductor chip 1. Therefore, the pitch between bump electrodes 4 becomes narrow as the number of bump electrodes 4 increases. When saying by FIG. 3, it corresponds to that the distance between bump electrodes 4a-4c becomes narrow.

Here, since the tip diameter of probe needles 6a-6c is about 10 μm˜20 μm, when the pitch of bump electrodes 4a-4c becomes narrow, contact between adjoining probe needles 6a-6c will pose a problem. This problem appears notably, when contacting adjoining probe needles 6a-6c in the same position of bump electrodes 4a-4c, respectively. Then, we are trying to contact probe needles 6a-6c in a different position of bump electrodes 4a-4c by making staggered arragement probe needles 6a-6c. Even if the pitch of bump electrodes 4a-4c becomes narrow by forming in this way, the problem that adjoining probe needles 6a-6c contact mutually is avoidable. Thus, it becomes a precondition of the present invention to arrange alternately probe needles 6a-6c.

Next, when the pitch of bump electrodes 4a-4c becomes still narrower, a new problem will occur. Bump electrodes 4a-4c are exactly arranged in a single line before implementation of the present invention. Thus, even when the structure which arranges exactly bump electrodes 4a-4c in a single line is taken, contact of adjoining probe needles 6a-6c can be prevented by arranging alternately adjoining probe needles 6a-6c. However, the problem shown below actualizes. That is, a certain amount of width exists in the accuracy of position of probe needles 6a-6c. For this reason, probe needles 6a-6c shift from an ideal position, and bump electrodes 4a-4c may be contacted. In this case, when the pitch of adjoining bump electrodes 4a-4c becomes narrow, the problem that probe needles 6a-6c shifted from ideal contact position contact the adjoining bump electrode which originally must not be contacted will occur. For example, bump electrode 4b contiguous to bump electrode 4a will be contacted as probe needle 6a in contact with bump electrode 4a shifts from an ideal contact position to right-hand side. That is, probe needle 6a will contact bump electrode 4b with which probe needle 6a originally must not contact. Via probe needle 6a, adjoining bump electrode 4a and adjoining bump electrode 4b are electrically connected, it short-circuits, and it becomes impossible then, to carry out a normal electrical property test. Thus, when the pitch between bump electrodes 4a-4c becomes narrow in the state where bump electrodes 4a-4c have been arranged in a single line exactly, contact between adjoining probe needles 6a-6c can be prevented by arranging alternately probe needles 6a-6c. However, the contact to the adjoining bump electrode by position drift of probe needles 6a-6c is nonavoidable.

So, in the present invention, bump electrodes 4a-4c have not been arranged in a single line exactly, but as shown in FIG. 3, in adjoining bump electrode 4a and adjoining bump electrode 4b, it arranges so that a partial area may shift. And we are trying to contact probe needles 6a-6c to the region which has shifted. Hereby, it can be prevented that an adjoining bump electrode short-circuits by position drift of probe needles 6a-6c.

In FIG. 3, the circle of the solid line shows probe needles 6a-6c which contact in an ideal position for bump electrodes 4a-4c. On the other hand, the circle of the dashed line shows the case where probe needles 6a-6c cause a position drift. For example, although not illustrated to FIG. 3, when bump electrodes 4a-4c are arranged in a single line exactly and probe needle 6a causes a position drift on right-hand side, it will be thought that probe needle 6a will contact not only bump electrode 4a but bump electrode 4b which originally must not contact. On the other hand, as shown in FIG. 3, bump electrodes 4a-4c are arranged in a single line, but in adjoining bump electrode 4a and adjoining bump electrode 4b, by arranging so that a partial area may be shifted, even if probe needle 6a causes a position drift on right-hand side, it can prevent contacting adjoining bump electrode 4b, for example. Thus, the present invention can prevent the short circuit between bump electrodes 4a and 4b resulting from a position drift of probe needle 6a by arranging so that a partial area may be shifted, arranging adjoining bump electrode 4a and adjoining bump electrode 4b in a single line. Although the partial area is shifted in adjoining bump electrode 4a and adjoining bump electrode 4b, this amount to shift is enough when carrying out by the region which contacts probe needle 6a from what is necessary being just to be able to prevent the short circuit between bump electrode 4a and bump electrode 4b resulting from a position drift of probe needle 6a. Namely, by shifting arrangement of adjoining bump electrode 4a and adjoining bump electrode 4b by the zone of contact of probe needle 6a, and contacting probe needle 6a to the shifted region, the effect that the short circuit defect between bump electrodes 4a and 4b resulting from a position drift of probe needle 6a can be prevented is acquired.

As mentioned above, the present invention has the feature in the point of not having arranged exactly bump electrodes 4a-4c in a single line, but arranging in adjoining bump electrode 4a and adjoining bump electrode 4b so that a partial area may shift. Although this characteristic point can be called structural feature of the present invention, there is the feature also in the point of contacting probe needles 6a-6c to the region which has shifted, and carrying out an electrical property test, further. This characteristic point is actualized also as a structural feature, although it can be called the manufacturing method feature.

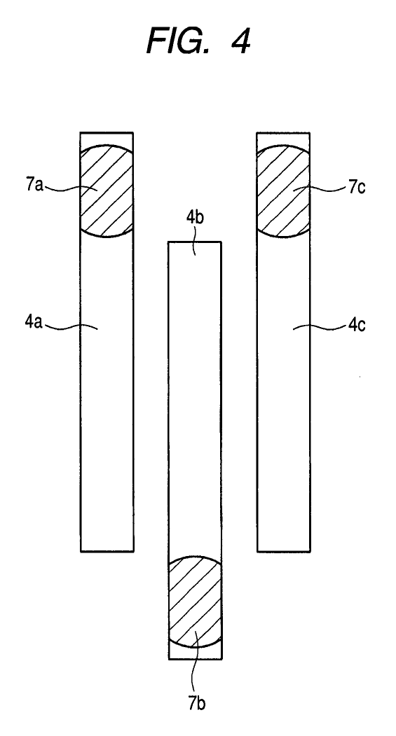

This point is explained. As shown in FIG. 3, probe needles 6a-6c are contacted to bump electrodes 4a-4c, and an electrical property test is carried out. At this time, as shown in FIG. 4, probe marks 7a-7c are formed in the region to which probe needles 6a-6c were contacted of the pressure when contacting probe needles 6a-6c. Therefore, it will turn out that probe needles 6a-6c were contacted to bump electrodes 4a-4c in which position, and the electrical property test was carried out. Then, as shown in FIG. 4 for example, when probe marks 7a-7c exist in the partial area of bump electrodes 4a-4c which has shifted, it turns out that the probe needle is contacted to the partial area of bump electrodes 4a-4c which has shifted. That is, probe needle 6a is kept from contacting adjoining bump electrode 4b in the present invention, by contacting probe needle 6a to the partial area which has shifted of bump electrode 4a, and carrying out an electrical property test, as shown in FIG. 3. Although this point can be called manufacturing method feature, when probe marks 7a generated in it when contacting probe needle 6a are formed in bump electrode 4a and probe marks 7a are seen, it will turn out that probe needle 6a is contacted to the partial area which has shifted of bump electrode 4a at a glance. For this reason, it turns out that a manufacturing method characteristic point actualizes also as a structural characteristic point.

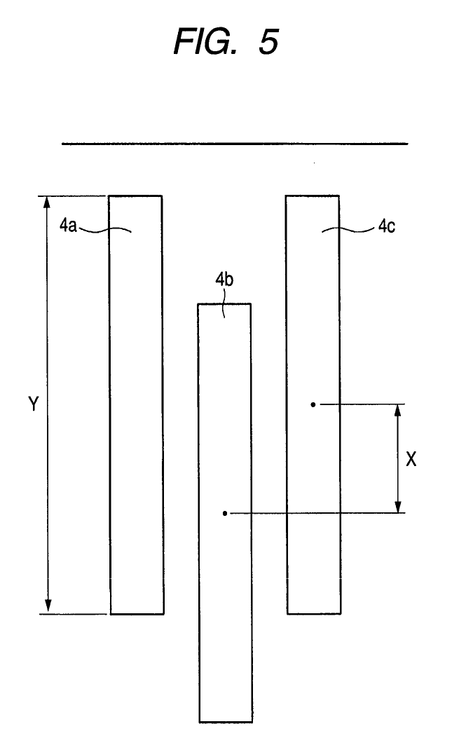

Next, although the characteristic structure of the present invention in which a bump electrode is arranged in a single line, and which is arranged by a partial area shifting mutually in the adjoining bump electrode is shown in FIG. 5, the definition of this structure is explained.

In FIG. 5, adjoining bump electrode 4b and adjoining bump electrode 4c are considered. It is assumed that the centroid position of bump electrode 4b and the centroid position of bump electrode 4c are shifted only X as shown in FIG. 5. The plane form of bump electrodes 4a-4c is a rectangle, and the length of a long side is set to Y. At this time, amount X of drifts of the centroid position of bump electrode 4b and the centroid position of bump electrode 4c is small compared with length Y of the long side of bump electrodes 4a-4c. In other words, amount X of drifts is smaller than the size for one bump electrode. Such arrangement is done to “bump electrodes 4a-4c being arranged in a single line, and a partial area shifting mutually and being arranged in an adjoining bump electrode,” on present application specifications. That is, it is the premise that bump electrodes 4a-4c shown in FIG. 5 are arranged in a single line, and it is assumed that the partial area has shifted in the adjoining bump electrode. Although bump electrode 4b and bump electrode 4c are mutually shifted with the structure shown in FIG. 5, it is considered that bump electrode 4b and bump electrode 4c which have shifted are arranged in a single line, and it is assumed that the partial area has shifted in bump electrode 4b and bump electrode 4c which are arranged in a single line.

On the other hand, FIG. 6 shows the example which is not included to the structure as used in a present application specification “bump electrodes 4a-4c are arranged in a single line, and a partial area shifts mutually and is arranged in an adjoining bump electrode.” Also in FIG. 6, although bump electrode 4b and bump electrode 4c have shifted, amount X of drifts of the centroid position of bump electrode 4b and the centroid position of bump electrode 4c is large compared with length Y of the long side of bump electrodes 4a-4c. In this case, although it can say that bump electrode 4a and bump electrode 4c are arranged in a single line, suppose that it cannot be said that bump electrode 4b is arranged in a single line with bump electrodes 4a and 4c. That is, with the structure shown in FIG. 6, bump electrodes 4a and 4c and bump electrode 4b are interpreted as what is arranged at two rows. Generally the structure shown in FIG. 6 is called staggered arragement. Therefore, the staggered arragement as used in a present application specification will not be included in the structure in which bump electrodes 4a-4c are arranged in a single line, and which is arranged by a partial area shifting mutually in the adjoining bump electrode.

Then, why staggered arragement is not included in the characteristic structure of the present invention is explained. As shown in FIG. 6, even if it makes staggered arragement the bump electrode for an output formed in a semiconductor chip, it is thought that the short circuit between the bump electrodes resulting from a position drift of a probe needle can be prevented like the present invention. However, in the driver (semiconductor chip) for LCD used for the liquid crystal display device of an STN method, it is required to reduce a manufacturing cost, and from a viewpoint of reducing a manufacturing cost, the bump electrode for an output was not made staggered arragement, but is arranged in a single line. Below, the reason for the more ability to reduce a manufacturing cost in the case arranged in a single line rather than the case making the bump electrode for an output staggered arragement is explained.

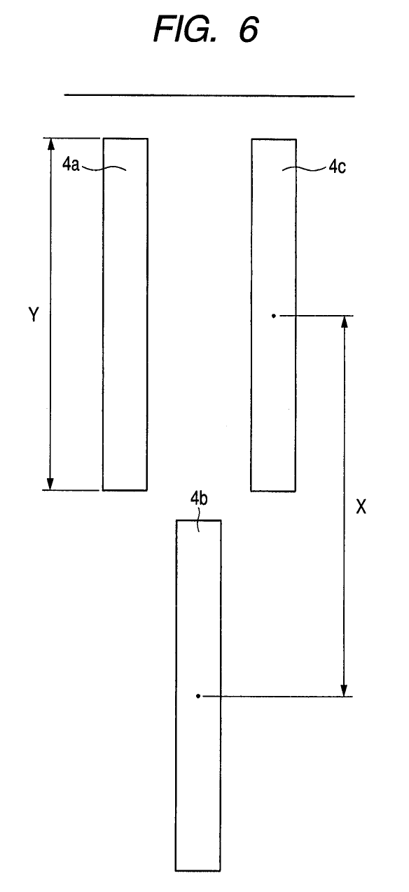

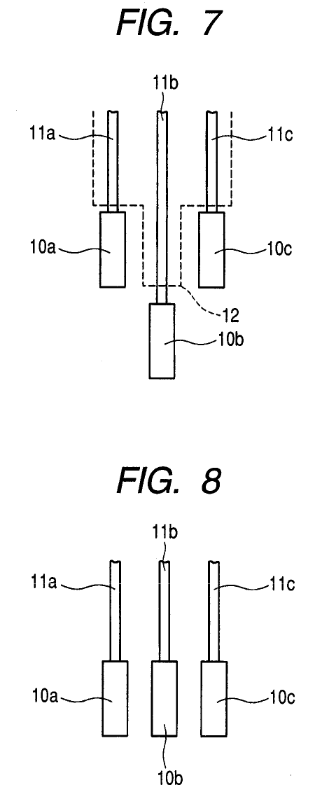

FIG. 7 is a drawing showing the glass substrate which mounts the driver (semiconductor chip) for LCD. In FIG. 7, the structure of the glass substrate when the bump electrode for an output currently formed in the semiconductor chip is staggered arragement is shown. That is, electrodes 10a-10c electrically connected to the bump electrode for an output currently formed in the semiconductor chip are formed in the glass substrate. These electrodes 10a-10c are alternately arranged corresponding to the bump electrode for an output currently formed in the semiconductor chip. Wirings 11a-11c are connected to electrodes 10a-10c currently formed in the glass substrate, respectively. These wirings 11a-11c are connected to the liquid crystal display section of a liquid crystal display device.

Here, an STN method is a simple matrix method and there is the feature that driver voltage becomes comparatively high, by an STN method. For this reason, it is necessary to enlarge area of the bump electrode formed in a semiconductor chip, and electrodes 10a-10c formed in a glass substrate also need to enlarge area in connection with this. Since electrodes 10a-10c formed in a glass substrate are arranged alternately, it is necessary to form wiring 11b connected to electrode 10b so that it may pass through between electrode 10a and electrode 10c. However, since the size of electrode 10a and electrode 10c becomes to some extent large, the space between electrode 10a and electrode 10c becomes narrow. It is necessary to form wiring 11b in this space that became narrow. The bump electrode currently formed in the semiconductor chip, and electrodes 10a-10c currently formed in the glass substrate are connected by an anisotoropic conductive film. There is a possibility that short circuit defect may occur by the electric conduction particles which form this anisotoropic conductive film between wiring 11b, and electrode 10a or electrode 10c.

For this reason, as shown in FIG. 7, it will be necessary to form coating by insulating film 12 on wirings 11a-11c comprising between electrode 10a and electrodes 10c. That is, when the bump electrode for an output currently formed in the semiconductor chip is made staggered arragement, in the glass substrate which mounts the semiconductor chip, it will be necessary to carry out coating by insulating film 12. Since coating of the insulating film 12 is done to a glass substrate, the problem that manufacturing cost rises by the part occurs. Since it is necessary to form the liquid crystal display device of an STN method by low cost, it is common not to take such a structure where a manufacturing cost rises.

FIG. 8 shows the structure of the glass substrate in the case of arranging the bump electrode for an output currently formed in the semiconductor chip in a single line. As shown in FIG. 8, electrodes 10a-10c formed in a glass substrate are arranged in a single line corresponding to the bump electrode for an output. And wirings 11a-11c are connected to electrodes 10a-10c arranged in a single line. Since electrodes 10a-10c are not staggered arragement and are arranged in a single line at this time, it becomes unnecessary to form so that wiring 11b may pass through between electrode 10a and electrodes 10c as shown in FIG. 7. It becomes unnecessary therefore, to carry out coating by an insulating film in the glass substrate which mounts a semiconductor chip. For this reason, the rise of a manufacturing cost can be suppressed. From the above thing, with the LCD driver (semiconductor chip) used for the liquid crystal display device of an STN method, the bump electrode for an output was not made staggered arragement, but is arranged in a single line.

In the LCD driver used for the liquid crystal display device of an STN method, it can be said from a viewpoint of a manufacturing cost that it is desirable to arrange the bump electrode for an output in a single line exactly. However, when realizing the narrowing of a pitch of a bump electrode and the bump electrode for an output is arranged in a single line exactly, the problem that an adjoining bump electrode short-circuits by position drift of a probe needle will occur.

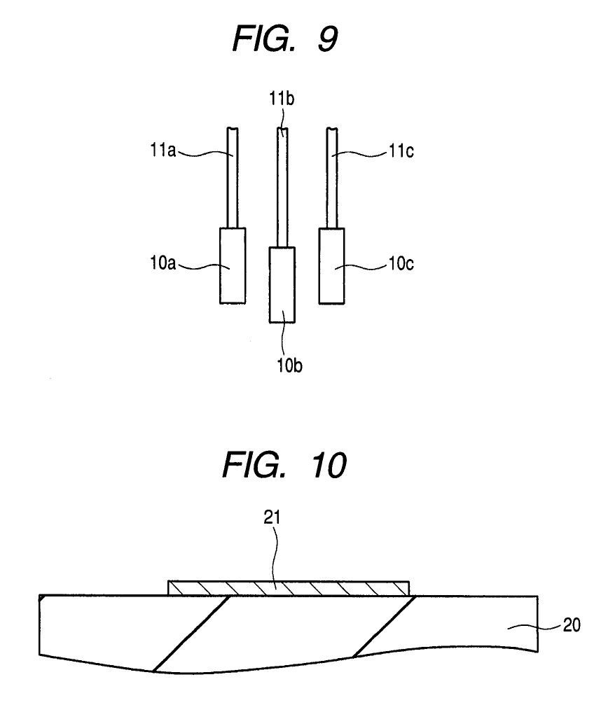

So, in the present invention, the structure that a bump electrode is arranged in a single line, and a partial area shifts mutually and is arranged in an adjoining bump electrode is adopted. According to this structure, the short circuit defect between the bump electrodes resulting from a position drift of a probe needle can be prevented. FIG. 9 shows the structure of the glass substrate which mounts a semiconductor chip, when doing arrangement of the bump electrode currently formed in the semiconductor chip to this structure. As shown in FIG. 9, electrodes 10a-10c formed in a glass substrate are also arranged in a single line corresponding to the bump electrode for an output formed in a semiconductor chip, and in the adjoining electrode, a partial area shifts mutually and is arranged. However, since it is not formed so that wiring 11b may pass along between electrode 10a and electrodes 10c thoroughly, as shown in FIG. 7, it is satisfactory even if it does not do coating by an insulating film to a glass substrate. Therefore, according to the present invention, the problem that an adjoining bump electrode short-circuits by position drift of a probe needle can be solved, without raising a manufacturing cost.

As for the amount of drifts from which each partial area has shifted, it is desirable that it is necessary minimum, although the structure that a bump electrode is arranged in a single line, and a partial area shifts mutually and is arranged in an adjoining bump electrode is taken in the present invention. This is because it will be formed so that wiring 11b shown in FIG. 9 may pass along between electrode 10a and electrodes 10c when the amount of drifts becomes large. That is, it is because it will be necessary to do coating of an insulating film to a glass substrate and the rise of a manufacturing cost is caused. That the amount of drifts is necessary minimum will say that the size of the partial area which has shifted should just be secured by the zone of contact which contacts a probe needle, when it thinks from what is necessary being just to be able to carry out the electrical property test by contact of a probe needle in the partial area which has shifted.

The semiconductor device in Embodiment 1 is formed as mentioned above, and the manufacturing method is explained below, referring to drawings.

First, although illustration is not done, for example, semiconductor elements, such as MOSFET (Metal Oxide Semiconductor Field Effect Transistor), are formed on the semiconductor substrate which consists of a silicon single crystal, and multilayer interconnection is formed on this semiconductor element. In FIG. 10, the wiring formed in the top layer is shown and it is omitting about a lower layer structure from this wiring formed in the top layer.

As shown in FIG. 10, insulating film 20 which consists of a silicon oxide film is formed. Insulating film 20 can be formed using the CVD (Chemical Vapor Deposition) method, for example. And titanium/titanium nitride film, an aluminum film, and titanium/titanium nitride film are laminated and formed on insulating film 20. Then, photolithography technology and etching technology are used and a laminated film is patterned. Pad 21 is formed by this patterning.

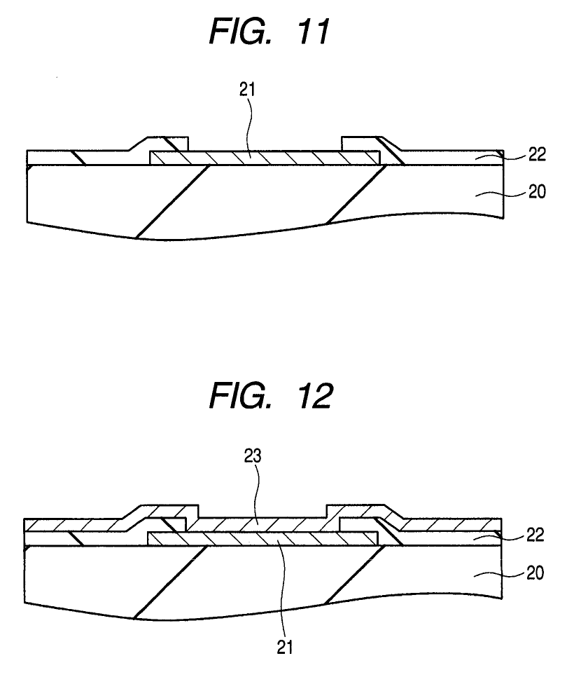

Then, as shown in FIG. 11, passivation film 22 is formed on insulating film 20 in which pad 21 was formed. Passivation film 22 is formed from a silicon nitride film, for example, can be formed with a CVD method, for example. Next, photolithography technology and etching technology are used and an opening is formed in passivation film 22. This opening was formed on pad 21 and has exposed the front surface of pad 21.

Next, as shown in FIG. 12, UBM (Under Bump Metal) film 23 is formed on passivation film 22 comprising the inside of an opening. UBM film 23 can be formed using the sputtering method, for example, is formed of a single layer film or laminated films, such as a titanium film, a nickel film, a palladium film, a titanium tungsten alloy film, a titanium nitride film, or a gold film, for example. UBM film 23 is a film which has the barrier function to suppress or prevent that the metallic element of the conductor film formed at a next step moves to a wiring etc., or that metallic elements, such as a wiring, move to the conductor film side on the contrary, in addition to the function which improves the adhesive property of a bump electrode, and pad 21 and passivation film 22 here. UBM film 23 will also have a role of an electrode in the plating step mentioned later.

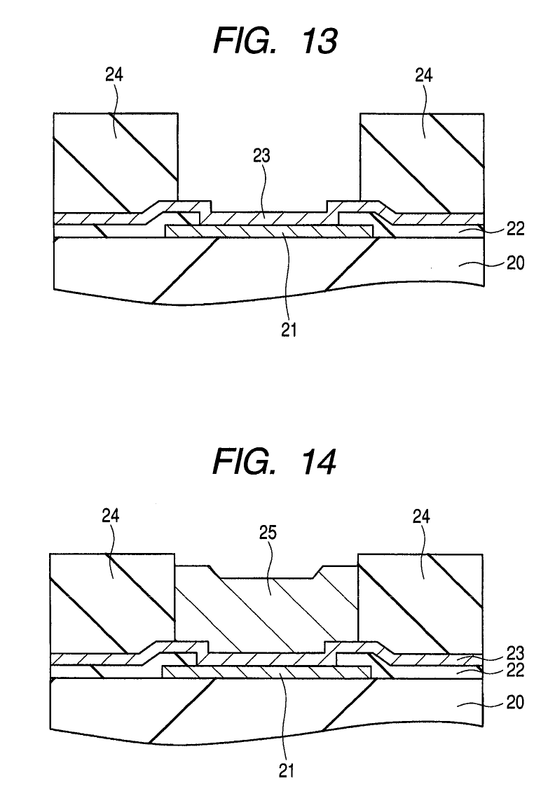

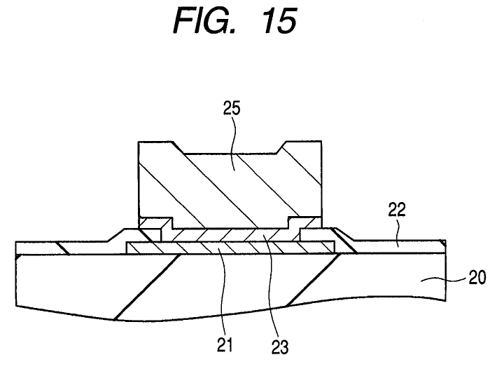

Then, as shown in FIG. 13, after applying resist layer 24 on UBM film 23, it patterns by performing exposure and a development to this resist layer 24. Patterning is performed so that resist layer 24 may not remain in a bump electrode formation area. And as shown in FIG. 14, bump electrode 25 is formed by for example, forming a gold film as a conductor film using an electroplating method. Then, as shown in FIG. 15, patterned resist layer 24 and UBM film 23 covered with resist layer 24 are removed. Hereby, bump electrode 25 which consists of a gold film and UBM film 23 is formed.

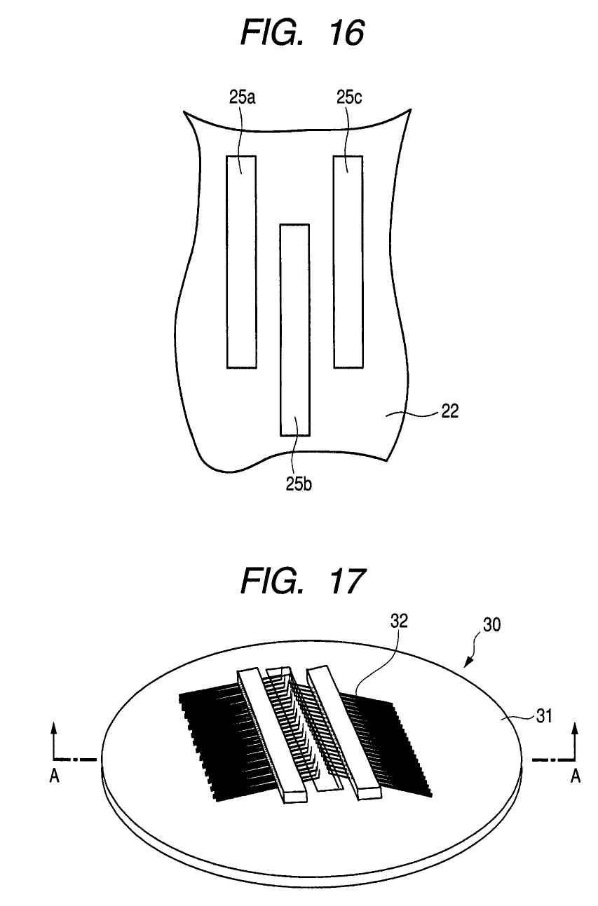

The plane configuration of the bump electrode formed in this way is shown in FIG. 16. As shown in FIG. 16, bump electrodes 25a-25c are formed on passivation film 22. These bump electrodes 25a-25c are arranged in a single line, and as the partial area has shifted in the adjoining bump electrode, they are formed. Forming bump electrodes 25a-25c can be manufactured at the steps which form the usual bump electrode as FIG. 10-FIG. 15 explained. That is, it passes through the almost same step as the method of forming a bump electrode in a single line exactly along one side of the chip area of a semiconductor wafer. Hereby, bump electrodes 25a-25c which are arranged in a single line, and which has the arrangement that the partial area has shifted in the adjoining bump electrode can be formed. A different point is a point of changing patterning of the resist layer for forming bump electrodes 25a-25c. Therefore, since the characteristic structure of Embodiment 1 is realizable only by changing patterning by photolithography technology, it can realize, without raising a manufacturing cost.

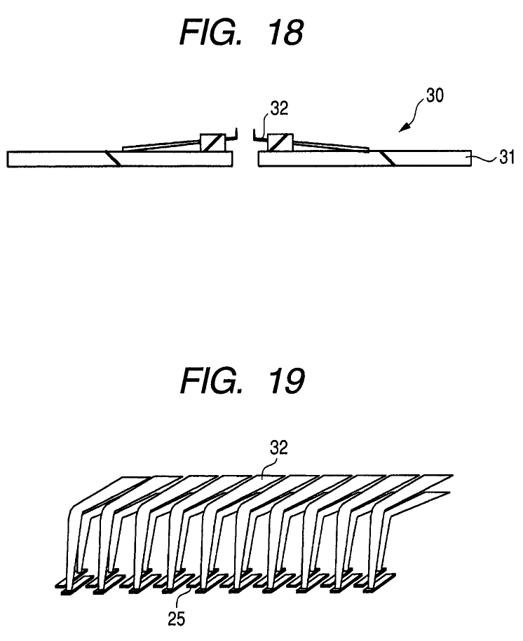

Next, an electrical property test is carried out to the semiconductor wafer in which bump electrodes 25a-25c were formed to the chip area. FIG. 17 is a drawing showing probe device (probe card) 30 of a cantilever method used by electrical property test. In FIG. 17, probe device 30 of the cantilever method has a structure by which a plurality of probe needles 32 are formed on probe substrate 31 of a circle configuration. FIG. 18 is a cross-sectional view showing the section cut by the A-A line of FIG. 17. As shown in FIG. 18, probe needle 32 is formed in probe substrate 31 in the state in which elastic deformation is possible. It is formed so that an electrical property test may be carried out by contacting the tip of probe needle 32 to a bump electrode. A state that probe needle 32 is contacted to the bump electrode is shown in FIG. 19. As shown in FIG. 19, bump electrode 25 is arranged in a single line, and in the adjoining bump electrode, a partial area shifts and it is arranged. Probe needle 32 by which staggered arragement was done touches bump electrode 25 arranged in this way.

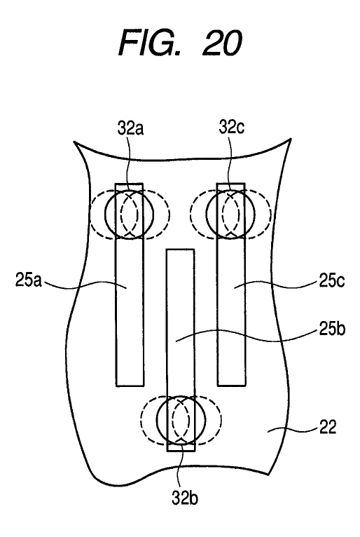

FIG. 20 is a plan view showing a state that an electrical property test is carried out contacting probe needles 32a-32c to bump electrodes 25a-25c. In FIG. 20, bump electrodes 25a-25c are arranged in a single line, and they are arranged so that a partial area may shift in an adjoining bump electrode. And probe needles 32a-32c are contacted to each partial area which has shifted, and the electrical property test is carried out. Since probe needles 32a-32c are contacted to the partial area of each bump electrode 25a-25c which has shifted at this time, even if probe needles 32a-32c cause a position drift, the bump electrode which adjoins is not contacted. At FIG. 20, the circle of a solid line shows the case where probe needles 32a-32c are contacted in the ideal position of bump electrodes 25a-25c. The circle of the dashed line shows the case where probe needles 32a-32c generate a position drift from this position. The partial area of bump electrodes 25a-25c has shifted, and probe needles 32a-32c are contacted to this partial area that has shifted as the circle of this dashed line also shows. Therefore, it turns out that probe needles 32a-32c do not contact an adjoining bump electrode even if probe needles 32a-32c cause a position drift, as the circle of a dashed line shows. For this reason, it can be prevented that an adjoining bump electrode short-circuits originating in a position drift of probe needles 32a-32c. That is, the electrical property test using probe needles 32a-32c can be conducted normally, without generating short circuit defect between adjoining bump electrodes, even if the pitch of bump electrodes 25a-25c becomes narrow. In particular, in Embodiment 1, since layout arrangement of bump electrodes 25a-25c is only changed, the reliability of an electrical property test can be improved, without increasing a manufacturing cost. That is, the manufacturing yield of a semiconductor device can be improved, without increasing a manufacturing cost. The probe needles 32a-32c themselves do not have to make a diameter thin, a conventional article can be used, and a manufacturing cost can be reduced compared with the case where a new probe needle is formed.

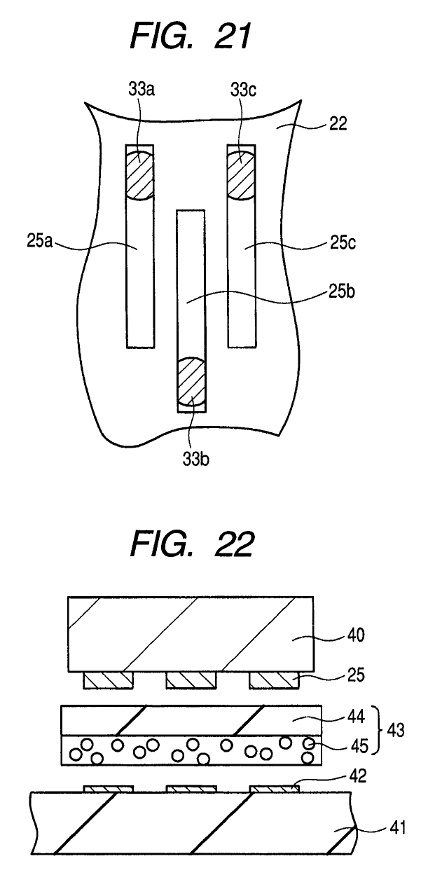

Next, FIG. 21 is a plan view showing bump electrodes 25a-25c after carrying out an electrical property test. As shown in FIG. 21, it turns out that probe marks 33a-33c formed in them when contacting a probe needle in bump electrodes 25a-25c are formed. When seeing these probe marks 33a-33c, it can be grasped whether the probe needle was contacted to which region of bump electrodes 25a-25c, and the electrical property test was carried out. For example, in FIG. 21, it turns out that a probe needle is contacted to the region which has shifted and the electrical property test is carried out from probe marks 33a-33c being formed in the partial area of bump electrodes 25a-25c which has shifted. Thus, the electrical property test in Embodiment 1 can be carried out.

Then, it individually separates to each semiconductor chip by doing dicing of the semiconductor wafer. Hereby, the semiconductor chip which is a driver for LCD is acquirable.

Then, the semiconductor chip formed as mentioned above is pasted up and mounted in a mounting substrate. FIG. 22 shows the case (COG:Chip On Glass) where semiconductor chip 40 is mounted in glass substrate 41. As shown in FIG. 22, semiconductor chip 40 and glass substrate 41 are connected via anisotoropic conductive film (ACF) 43. Bump electrode 25 is formed in semiconductor chip 40, and is mounted so that this bump electrode 25 may be connected to electrode 42 of glass substrate 41. Between bump electrode 25 and electrode 42, anisotoropic conductive film 43 which consists of insulating film 44 and conductive particle 45 intervenes. Bump electrode 25 and electrode 42 are electrically connected by conductive particle 45 included in anisotoropic conductive film 43.

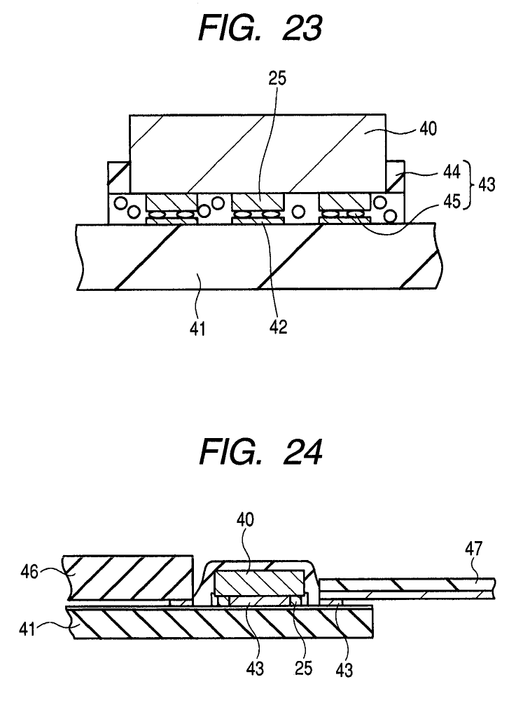

As shown in FIG. 23, with semiconductor chip 40 and glass substrate 41, conductive particle 45 in anisotoropic conductive film 43 is crushed, and conductivity is secured. That is, although conductive particle 45 is included in anisotoropic conductive film 43, conductivity actualizes this conductive particle 45 by being crushed. Therefore, electric connection through conductive particle 45 between bump electrode 25 and electrode 42 is made the sure thing by securing the area of bump electrode 25 and crushing many conductive particles 45. Thus, it is necessary to adhere with glass substrate 41 via anisotoropic conductive film 43, and as many conductive particles 45 as possible are made to intervene between bump electrode 25, and electrode 42 of glass substrate 41 in the driver for LCD (semiconductor chip 40). Therefore, bump electrode 25 currently formed in the driver for LCD has a rectangular big area. In detail, the plane form of bump electrode 25 for an output comprises a rectangle, and the length of the long side is longer than a length of one side of the bump electrode for an input. Bump electrode 25 for an output is arranged so that the long side may extend and exist in the direction which intersects the long side of semiconductor chip 40. If this makes many conductive particles 45 only intervene between bump electrode 25, and electrode 42 of glass substrate 41, even if it will form the plane form with a square, for example, it will be satisfactory when the area of bump electrode 25 is large. However, when bump electrode 25 is formed with a square, in the long side direction of semiconductor chip 40, it becomes difficult to improve the number of the bump electrodes which can be arranged by a single tier. On the other hand, when arranging so that it may form with rectangular form and the long side of bump electrode 25 may extend and exist further in the direction which intersects the long side of semiconductor chip 40, it is possible to improve the area of bump electrode 25, arranging more bump electrodes 25.

FIG. 24 is a cross-sectional view showing a state that semiconductor chip 40 is mounted in glass substrate 41. As shown in FIG. 24, other glass substrate (second glass substrate) 46 is mounted in glass substrate (first glass substrate) 41, and, hereby, the displaying unit of LCD is formed. And on glass substrate 41 near the displaying unit of LCD, semiconductor chip 40 which is a driver for LCD is mounted. Bump electrode 25 is formed in semiconductor chip 40, and bump electrode 25, and the electrode formed on glass substrate 41 are connected via anisotoropic conductive film 43. Glass substrate 41 and flexible printed circuit board (Flexible Printed Circuit) 47 are also connected by anisotoropic conductive film 43. Thus, in semiconductor chip 40 mounted on glass substrate 41, bump electrode 25 for an output is electrically connected to the displaying unit of LCD, and the bump electrode for an input is connected to flexible printed circuit board 47.

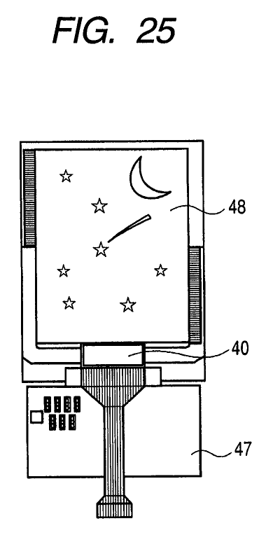

FIG. 25 is a drawing showing the entire configuration of LCD. As shown in FIG. 25, displaying unit 48 of LCD is formed on the glass substrate, and a picture is displayed on this displaying unit 48. On the glass substrate near the displaying unit 48, semiconductor chip 40 which is a driver for LCD is mounted. Flexible printed circuit board 47 is mounted near the semiconductor chip 40, and semiconductor chip 40 which is a driver for LCD is mounted between flexible printed circuit board 47 and displaying unit 48 of LCD. Thus, the liquid crystal display device (LCD) which mounts semiconductor chip 40 on glass substrate 41 can be manufactured.

### Embodiment 2

Although the Embodiment 1 explained the LCD driver used for the liquid crystal display device of an STN method, Embodiment 2 explains the LCD driver used for the liquid crystal display device of a TFT (Thin Film Transistor) method.

A TFT method is one of the drive systems of a liquid crystal display called an active-matrix method. Concretely, it is the thing that the transistor which is an active element is arranged to each intersection region (cell) in addition to the structure in which the direction of the liquid crystal molecule in an intersection region (cell) changes, and a liquid crystal display device drives when lead wire is spread around in the two directions of an X axial direction and a Y axial direction which cross mutually and voltage is applied to lead wire from the two directions of an X axial direction and a Y axial direction. As for an active element, an ON/OFF state changes with the voltage of the lead wire of an X axial direction, for example. When an active element is in an ON state and voltage is applied also to the lead wire of a Y axial direction, the direction of the target liquid crystal molecule in an intersection region will be controlled. Hereby, only the target cell can be operated surely. As an advantage of a TFT method, there is the feature that there are few afterimages and an angle of visibility is also wider than a simple matrix method. Further, it has the feature that contrast is also high and reaction velocity is quick.

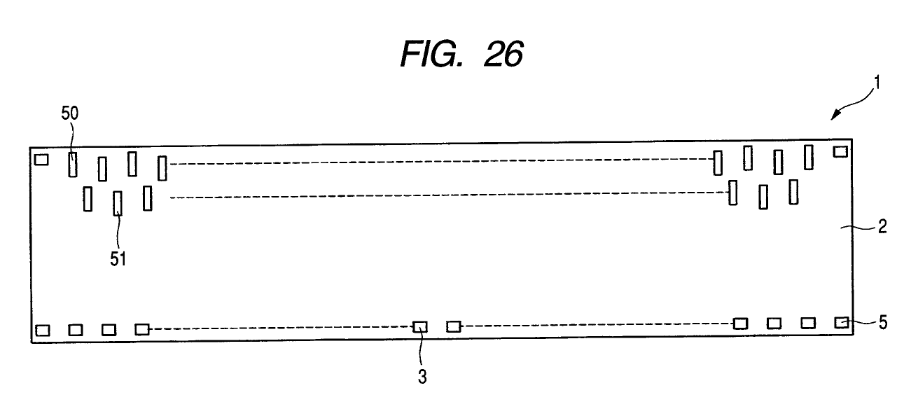

FIG. 26 is a drawing showing the layout structure of semiconductor chip (driver for LCD) 1 used for the liquid crystal display device of a TFT method. As for the point that semiconductor chip 1 in Embodiment 2 differs from semiconductor chip 1 in the Embodiment 1, it is the point that the bump electrode for an output is arranged by plural lines, and is alternate in Embodiment 2 although the bump electrode for an output was arranged in a single line in the Embodiment 1.

As shown in FIG. 26, in Embodiment 2, as a bump electrode for an output, bump electrode 50 is formed in the first row, and bump electrode 51 is formed in the second row. Alternate arrangement is formed with this bump electrode 50 and bump electrode 51. Thus, in the driver for LCD used for the liquid crystal display device of a TFT method, the bump electrode for an output is not arranged in a single line, and is arranged alternately in many cases. When the bump electrode for an output is arranged alternately and the pitch of the bump electrode for an output becomes narrow, a possibility that the short circuit defect by position drift of a probe needle may occur between the bump electrodes which are arranged adjoining in the same row will occur. When arranging the bump electrode for an output in a single line like the LCD driver of an STN method, it actualizes more, but this problem may be generated even when arranging the bump electrode for an output to plural lines like the LCD driver of a TFT method.

So, in Embodiment 2, as shown in FIG. 26, it arranges so that the partial area of the bump electrode which adjoins the same row may be shifted with both bump electrode 50 arranged by the first row and bump electrode 51 arranged by the second row. Hereby, the short circuit defect by position drift of a probe needle can be prevented between the bump electrodes which are arranged adjoining the same row.

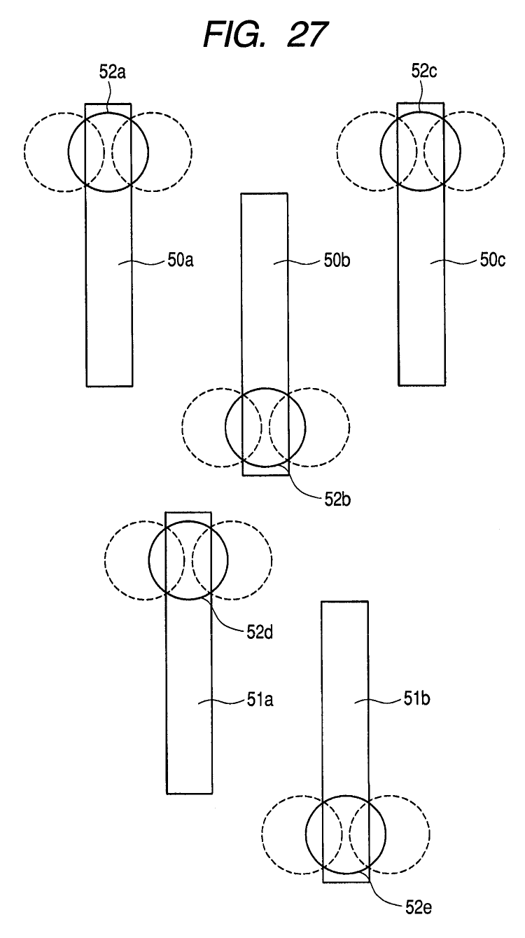

FIG. 27 is a drawing showing the example for which probe needles 52a-52e are contacted with the structure which shifted the partial area of the bump electrode which is arranged adjoining the same row in bump electrodes 50a-50c, 51a, and 51b which did staggered arragement. In FIG. 27, bump electrodes 50a-50c are arranged by the first row, for example, in bump electrode 50a and bump electrode 50b which are adjoined and arranged by the first row, a partial area shifts and is arranged. And probe needles 52a and 52b touch the partial area arranged by shifting, respectively. Therefore, even if, for example, probe needle 52a contacted to bump electrode 50a causes a position drift on right-hand side, bump electrode 50b is not contacted. At FIG. 27, the circle of a solid line shows the case where a probe needle is contacted in an ideal position, and the circle of the dashed line shows the case where it shifts from an ideal position.

Similarly, also as for bump electrode 51a and bump electrode 51b which are adjoined and arranged by the second row, the partial area is shifted mutually. And probe needles 52d and 52e are contacted in the partial area shifted mutually. For this reason, even if probe needle 52d causes a position drift on right-hand side, bump electrode 51b is not contacted. Therefore, it can be prevented that an adjoining bump electrode short-circuits with bump electrodes 50a-50c, 51a, and 51b by which staggered arragement was done originating in a position drift of probe needles 52a-52e. That is, the electrical property test using probe needles 52a-52e can be conducted normally, without generating short circuit defect between adjoining bump electrodes, even if the pitch of bump electrodes 50a-50c or bump electrodes 51a and 51b becomes narrow.

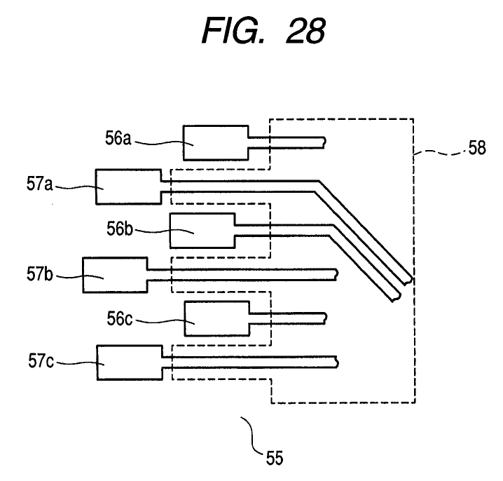

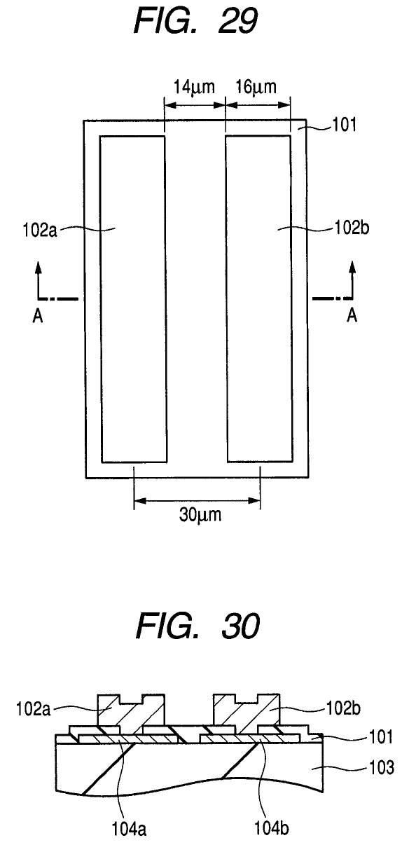

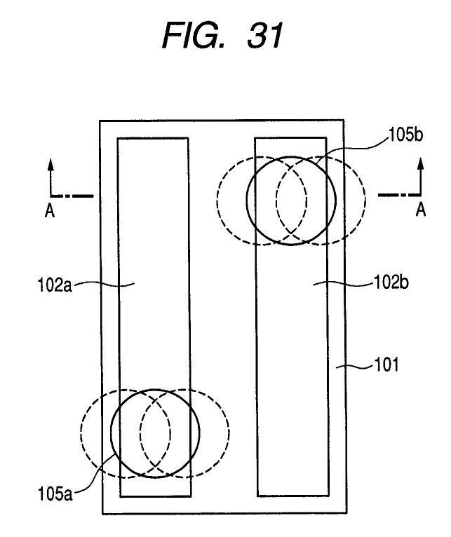

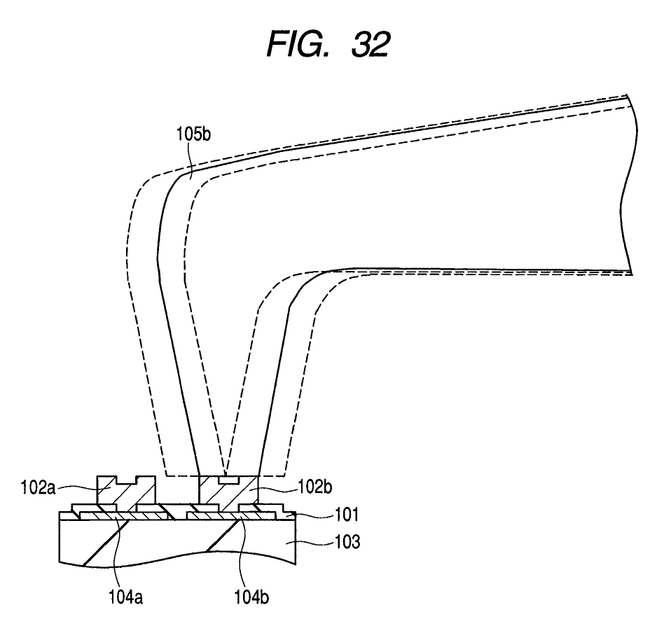

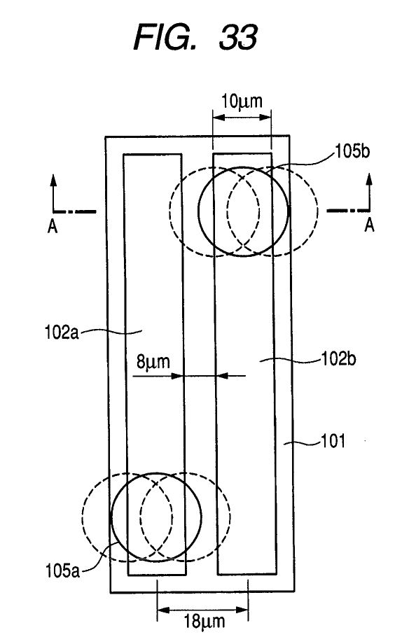

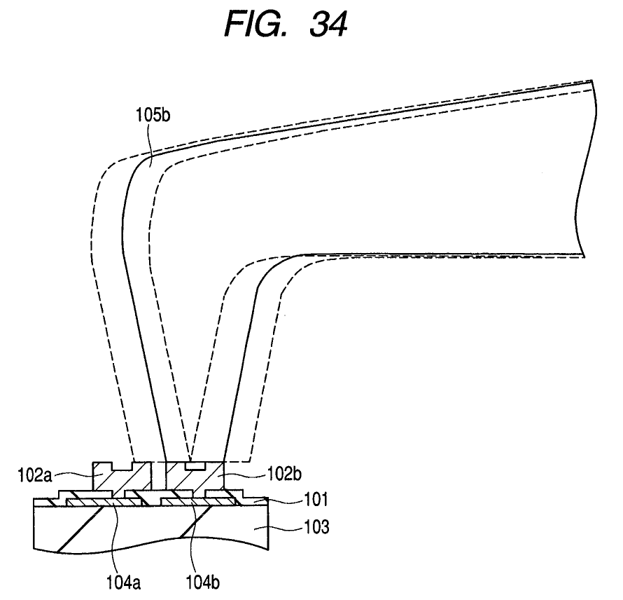

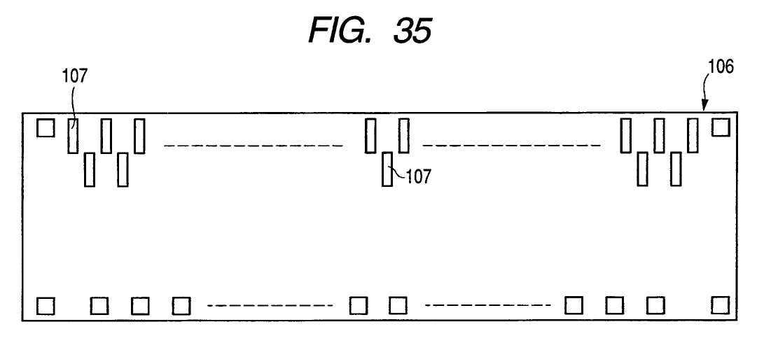

FIG. 28 is a drawing showing the glass substrate which mounts the driver for LCD (semiconductor chip). In FIG. 28, the structure of the glass substrate when the bump electrode for an output currently formed in the semiconductor chip is staggered arragement is shown. That is, electrodes 56a-56c, and 57a-57c electrically connected to the bump electrode for an output currently formed in the semiconductor chip are formed in the glass substrate. These electrodes 56a-56c, and 57a-57c are alternately arranged corresponding to the bump electrode for an output currently formed in the semiconductor chip. The wiring is connected to electrodes 56a-56c, and 57a-57c currently formed in the glass substrate, respectively. This wiring is connected to the liquid crystal display section of a liquid crystal display device.

Here, between electrodes 56a-56c, the wiring connected to electrodes 57a-57c passes. Since it is narrow between electrodes 56a-56c, the wiring connected to electrodes 57a-57c short-circuits easily. So, in Embodiment 2, coating by insulating film 58 is carried out to the wiring. Hereby, the short circuit defect between a wiring can be prevented.

Since it is necessary to reduce a manufacturing cost in the case of an STN method, it is necessary to avoid doing coating by an insulating film to a glass substrate. Therefore, the bump electrode currently formed in a semiconductor chip has not been arranged alternately, and it has been arranged in a single line. On the other hand, in the case of a TFT method, since emphasis is put by improving quality rather than reducing a manufacturing cost, it is satisfactory even if it carries out coating by an insulating film to a glass substrate. Since arrangement of a bump electrode is arranged alternately in many cases, in the case of a TFT method, it is necessary to perform coating by an insulating film to a glass substrate, and it needs to improve the reliability of a wiring.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

The embodiment showed the example which mounts a semiconductor chip (LCD driver) in a glass substrate. However, the present invention can be applied, not only this but when a semiconductor chip is mounted in a printed-circuit board (COB; Chip On Board) or it mounts a semiconductor chip in a film substrate.

The present invention can be broadly used for the manufacture which manufactures a semiconductor device.

What is claimed is:

1. A method of manufacturing a semiconductor device, comprising the steps of:
(a) forming a plurality of bump electrodes in a chip area of a semiconductor wafer; and
(b) performing an electrical property test by contacting a probe needle of staggered arrangement with the bump electrodes;
wherein bump electrodes which adjoin to each other among the bump electrodes are formed in such a manner that each partial area of the bump electrodes is shifted mutually.

2. A method of manufacturing a semiconductor device according to claim 1, wherein
a plane form of the bump electrodes is a rectangle; and
in a long side direction of the bump electrode, a bump electrode which adjoins each other among the bump electrodes is formed each partial area shifting mutually.

3. A method of manufacturing a semiconductor device according to claim 1, wherein
a bump electrode which adjoins each other among the bump electrodes is shifted mutually only by a part of a region which contacts the probe needle.

4. A method of manufacturing a semiconductor device according to claim 1, further comprising the steps of:
(c) individually separating the semiconductor wafer to a plurality of semiconductor chips; and
(d) mounting each of the semiconductor chips in a glass substrate via the bump electrodes.

5. A method of manufacturing a semiconductor device according to claim 1, further comprising the steps of:
(c) individually separating the semiconductor wafer to a plurality of semiconductor chips; and
(d) mounting each of the semiconductor chips in a wiring substrate via the bump electrodes;
wherein the bump electrodes and a terminal of the wiring substrate are electrically connected via a conductive particle.

6. A method of manufacturing a semiconductor device according to claim 5, wherein
the wiring substrate is a glass substrate.

7. A method of manufacturing a semiconductor device according to claim 1, wherein
the probe needle is used with a probe device of a cantilever method.

8. A method of manufacturing a semiconductor device according to claim 1, wherein
the chip area is rectangular shape; and
the bump electrodes are arranged in a single line along one side of the chip area.

9. A method of manufacturing a semiconductor device according to claim 1, wherein
the chip area is rectangular shape; and
the bump electrodes are arranged by plural lines along one side of the chip area.

10. A method of manufacturing a semiconductor device according to claim 1, wherein
the step (b) conducts an electrical property test by contacting the probe needle over each partial area of the bump electrodes.

11. A method of manufacturing a semiconductor device according to claim 10, wherein
over each partial area of the bump electrodes, a probe mark made when contacting the probe needle is formed.

12. A method of manufacturing a semiconductor device according to claim 10, wherein
in a bump electrode which adjoins each other among the bump electrodes, an electrical property test is conducted contacting the probe needle to a region shifted mutually.

13. A method of manufacturing a semiconductor device according to claim 12, wherein
a probe mark is formed in a region shifted mutually in a bump electrode which adjoins each other among the bump electrodes.

14. A method of manufacturing a semiconductor device according to claim 1, wherein
in a bump electrode which adjoins each other among the bump electrodes, a position of a center of gravity of an adjacent bump electrode has shifted, and an amount of position drifts of the center of gravity is smaller than a size for one bump electrode.

15. A semiconductor device, comprising:
a semiconductor chip in which a plurality of bump electrodes are formed;
wherein each partial area of bump electrodes which adjoins to each other among the bump electrodes is shifted mutually.

16. A semiconductor device according to claim 15, wherein
in a bump electrode which adjoins each other among the bump electrodes, a region shifted mutually turns into a zone of contact to which a probe needle is contacted.

17. A semiconductor device according to claim 15, wherein
in a bump electrode which adjoins each other among the bump electrodes, a probe mark made when contacting a probe needle is formed in a region shifted mutually.

18. A semiconductor device according to claim 15, further comprising:
a glass substrate;
wherein the semiconductor chip and the glass substrate are connected via the bump electrodes.

19. A semiconductor device according to claim 18, wherein
the semiconductor chip is a driver for LCD which drives a liquid crystal display element.

20. A semiconductor device according to claim 19, wherein
the semiconductor chip is the driver for LCD which drives a liquid crystal display device of an STN method.

21. A semiconductor device according to claim 19, wherein
the semiconductor chip is the driver for LCD which drives a liquid crystal display device of a TFT method.
